(19) United States
(12) Patent Application Publication
(10) Pub. No.: US 2004/0238897 A1
(43) Pub. Date: Dec. 2, 2004

(54) MOS semiconductor device

(76) Inventor: Amane Oishi, Kamakura-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/712,039

(22) Filed: Nov. 14, 2003

(30) Foreign Application Priority Data
May 30, 2003 (JP) 2003-154246

(51) Int. Cl. H01L 31/119

(52) U.S. Cl. 257/369

(57) ABSTRACT

A semiconductor device comprising an active area of a MOSFET which is separated by an element isolation area on a semiconductor substrate, at least one gate electrode provided over the active area, and at least one source/drain contact formed on a surface of the active area at one side of the gate electrode, wherein the gate electrode has a shape to vary so that a gate length decreases with increasing a distance from a position of the source/drain contact along the gate electrode.

### CROSS-REFERENCE TO RELATED APPLICATIONS

This application is based upon and claims the benefit of priority from the prior Japanese Patent Application No. 2003-154246, filed May 30, 2003, the entire contents of which are incorporated herein by reference.

### BACKGROUND OF THE INVENTION

1. Field of the Invention

The present invention relates to a MOS-type semiconductor device, and in particular, to the structure of a gate electrode of a MOS field effect transistor (MOSFET) having an insulated gate structure, which is applied to, for example, a complementary MOS large scale integration (CMOSLSI) circuit.

2. Description of the Related Art

As elements in a CMOSLSI have become more and more fine-shrunk, the size of an active area (AA) in which a MOSFET is formed has decreased correspondingly. Consequently, the parasitic resistance of the active area is not negligible. This will be described below.

FIG. 12 is a conventional example of a planar pattern of a CMOS inverter formed in a CMOSLSI.

In FIG. 12, reference numeral 120 denotes, for example, a shallow trench type isolation (STI) area formed on a semiconductor substrate. Reference numeral 121 denotes an active area of a PMOSFET surrounded by the STI area 120. Reference numeral 122 denotes an active area of an NMOSFET surrounded by the STI area 120. Reference numeral 123 denotes a gate electrode formed on channel areas of the active areas via a gate insulating film and passing through a central portion of each of the active areas. Metal silicide is often formed on the surface of diffusion layers for drain and source areas of the active areas 121 and 122 and on the surface of the gate electrode 123.

Contacts (corner contacts) 124 for drain contact areas and source contact areas are each formed in the active areas 121 and 122 on its diagonal line and close to the corner of the metal silicide at a corresponding side of the gate electrode 123.

FIG. 13 is a sectional view showing an example of the structure of a MOSFET constituting the CMOS inverter shown in FIG. 12.

In FIG. 13, reference numerals 130, 131, and 132 denote a semiconductor substrate, source/drain areas, and extension areas, respectively. Reference numerals 133, 134, and 135 denote a channel area, a gate insulating film, and a gate electrode, respectively. Reference numerals 136, 137, and 138 denote a gate sidewall insulating film, a drain contact (plug), and a source contact (plug), respectively.

A parasitic resistance is present in each of the above areas and in each of the junction areas between the semiconductor substrate and each of the drain contact area, source contact area, and source/drain areas.

FIG. 14 shows an example of a current path for a current flowing through the source/drain area 121 of one of the MOSFTEs of the CMOS inverter shown in FIG. 12.

As the CMOSFET becomes more and more fine-shrunk, the distance A between the STI area and the gate electrode 123 decreases as shown in FIG. 14. In particular, for a MOSFET having corner contacts 124a and 124b, the decrease in the distance A increases the resistance R1 of the silicide on the drain area along the gate electrode and the resistance of the silicide on the source area along the gate electrode. Consequently, a large parasitic resistance is offered. The mechanism of a decrease in the driving force of the MOSFET caused by this increase of the parasitic resistance is classified into two types as described below.

(1) The drain potential of the MOSFET decreases below the operating power source voltage Vdd of the MOSFET. Accordingly, as the distance from the drain contact 124a increases, a voltage effectively applied between the source and drain of the MOSFET decreases. Thus, the effective drain voltage of a cross section perpendicular to the gate electrode 123 decreases consistently with increasing distance between the drain contact 124a and a position x along the longitudinal direction of the gate electrode 123. Accordingly, the level of DIBL (Drain Induced Barrier Lowering) decreases excessively, thus reducing the driving force of the MOSFET.

(2) The source potential of the MOSFET raises above 0 Volt. Accordingly, as the distance from the drain contact 124b increases, the voltage effectively applied between the source and drain of the MOSFET decreases. Thus, the effective drain voltage of the cross section perpendicular to the gate electrode 123 decreases consistently with increasing distance between the source contact 124b and the position x in the longitudinal direction of the gate electrode 123. Accordingly, the level of DIBL decreases excessively, thus reducing the driving force. In this case, as the distance from the source contact 124b increases, the potential of a well area increases relatively below the source potential. Consequently, as the distance from the source contact 124b increases, the driving force is additionally reduced by a substrate bias effect. The amount of decrease in driving force is thus larger than that in the case (1). This is shown in FIG. 15.

FIG. 15 shows that the driving force (on current) of the MOSFET shown in FIG. 14 decreases consistently with increasing distance between the position of the source contact 124b and the position x along the gate electrode 123 in the longitudinal direction thereof. This graph shows a comparison of the case in which there is a silicide resistance on the drain and source diffusion layers with the case in which there is no silicide resistance on these layers.

For example, Jpn. Pat. Appln. KOKAI Publication No. 7-131013 shows a MOS type transistor in which at least that part of the end of a gate which is opposite to a drain is curved or inclined. However, this publication does not specify the relationship between the gate length and the position of a contact.

As described above, in the conventional semiconductor devices, a reduction in the size of the MOSFET element disadvantageously increases the resistance of the silicide on the drain and source diffusion layers in the active area. As a result, more attention is being paid to a decrease in the speed of circuit operations associated with a decrease in the driving force of the MOSFET caused by an increase in parasitic resistance. In particular, if corner contacts are used, the silicide resistance takes up a larger percentage of the parasitic resistance and its adverse effect is thus more serious. It is unavoidable that the parasitic resistance increases with decreasing size of the MOSFET as described above. Therefore, it becomes inevitably difficult to advantageously develop more fine-shrunk structures in the future in expectation of an increase in the speed of circuit operations.

### BRIEF SUMMARY OF THE INVENTION

According to a first aspect of the present invention, there is provided a semiconductor device comprising an active area of a MOSFET which is separated by an element isolation area on a semiconductor substrate; at least one gate electrode provided over the active area; and at least one source/drain contact formed on a surface of the active area at one side of the gate electrode, wherein the gate electrode has a shape to vary so that a gate length decreases with increasing a distance from a position of the source/drain contact along the gate electrode.

According to a second aspect of the present invention, there is provided a semiconductor device comprising an active area which is separated by an element isolation area on a semiconductor substrate and in which a plurality of MOSFETS are arranged so as to be connected in series, a plurality of gate electrodes juxtaposed with each other over the active area, a first source/drain contact formed at a surface of the active area at one side of the gate electrodes, and a second source/drain contact formed at the surface of the active area at another side of the gate electrodes, wherein one of the gate electrodes located closest to at least one of the first and second source/drain contacts is formed to vary so that a gate length thereof decreases with increasing distance from a position of corresponding one of the first and second source/drain contacts along the one of the gate electrodes.

### BRIEF DESCRIPTION OF THE SEVERAL VIEWS OF THE DRAWING

FIG. 1A is a diagram showing an example of a planar pattern of a MOSFET in a CMOS inverter according to a first embodiment of the present invention;

FIG. 1B is a diagram showing an example of a planar pattern of a MOSFET in a CMOS inverter according to a second embodiment of the present invention;

FIG. 2 is a plan view showing a first modification of the first embodiment shown in FIG. 1A;

FIG. 3 is a plan view showing a second modification of the first embodiment shown in FIG. 1A;

FIG. 4 is a diagram showing an example of a planar pattern of one of the MOSFETs of a CMOS inverter according to a third embodiment of the present invention;

FIG. 5 is a diagram showing an example of a planar pattern of one of the MOSFETs of a CMOS inverter according to a fourth embodiment of the present invention;

FIG. 6 is a diagram showing an example of a planar pattern of a MOSFET circuit area in which a plurality of MOSFETs are arranged so as to be connected in series according to a modification of the forth embodiment;

FIG. 7 is a diagram showing an example of a planar pattern of a MOSFET circuit area in which a plurality of MOSFETs are arranged so as to be connected in series according to a fifth embodiment of the present invention;

FIG. 8 is a plan view illustrating a path of a current flowing through a gate electrode in the MOSFET shown in FIG. 1 as well as its parasitic resistance;

FIG. 9 is a graph showing the relationship between the distance from a source contact along a gate electrode and a gate length in the MOSFET shown in FIG. 1;

FIG. 10 is a characteristic diagram showing the relationship between the distance and an on current in a MOSFET for which the relationship between the distance and the gate length has been determined as shown in FIG. 9;

FIG. 11 is a characteristic diagram showing the magnitude of an on current obtained if a standby current remains fixed, by comparing a conventional MOSFET with the MOSFET for which the relationship between the distance and the gate length has been determined as shown in FIG. 9;

FIG. 12 is a diagram showing a conventional example of a planar pattern of a CMOS inverter formed in an LSI;

FIG. 13 is a sectional view showing an example of the structure of one of the MOSFETs constituting the CMOS inverter shown in FIG. 12;

FIG. 14 is a plan view illustrating a path of a current flowing through a particular position of a gate electrode in one of the MOSFETs constituting the CMOS inverter shown in FIG. 12; and

FIG. 15 is a characteristic diagram showing that the driving force of the MOSFET shown in FIG. 14 decreases with increasing distance between the position of a source contact as a reference and the position of a gate electrode in a longitudinal direction.

### DETAILED DESCRIPTION OF THE INVENTION

Embodiments of the present invention will be described below in detail with reference to the drawings.

### First Embodiment

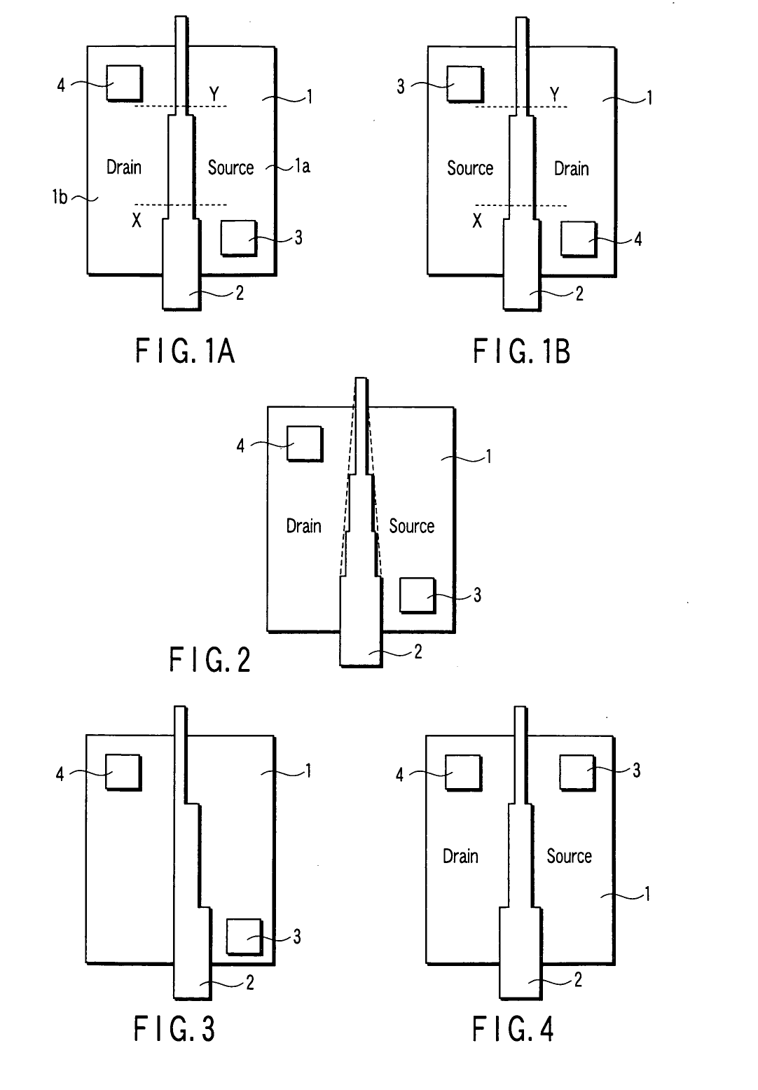

FIG. 1A shows an example of a planar pattern of one of a PMOSFET and an NMOSFET in a CMOS inverter according to a first embodiment of the present invention.

In FIG. 1A, reference numeral 1 denotes an active area of a MOSFET separated by an element isolation area on a semiconductor substrate. Reference numeral 2 denotes a gate electrode formed so as to pass over the active area 1. Reference numerals 3 and 4 denote source/drain contacts formed in contact with surfaces of silicide layers 1a, 1b formed on the active area 1 at the opposite sides of the gate electrode 2. However, in the following embodiments, the source/drain contact 3 is denoted as a source contact 3 and the source/drain contact 4 is denoted as a drain contact 4.

If only one gate electrode 2 is provided for one active area 1 and one source contact 3 and one drain contact 4 are diagonally arranged in the active area 1 as described above, then the planar pattern of the gate electrode 2 is formed so that a gate length (or the width of the gate electrode 2, or the channel length of the MOSFET) decreases with increasing distance from the position of the source contact 3 along the longitudinal direction of the gate electrode 2 (or the channel width direction of the MOSFET). In the present embodiment, the planar pattern of the gate electrode 2 has a shape which is laterally symmetric and which varies step by step among a plurality of levels (in this embodiment, among three levels).

With this arrangement, in a MOSFET having only one gate electrode 2 in the active area 1 as in the case with, for example, a CMOS inverter, DIBL (Drain Induced Barrier Lowering) can be adjusted for MOSFET operations in a cross section perpendicular to the gate electrode 2 so as to be nearly equal at any positions with respect to the gate electrode 2. Specifically, MOSFET operations in the cross section perpendicular to the gate electrode 2 near the drain contact 4 at the position Y shown in FIG. 1A can be adjusted to undergo DIBL equal to or more marked than that acting on MOSFET operations in the cross section perpendicular to the gate electrode 2 near the source contact 3 at the position X shown in FIG. 1A.

Consequently, the DIBL can be adjusted at any desired position x along the gate electrode 2 for MOSFET operations in a cross section perpendicular to the gate electrode 2, so that a decrease in the driving force of the MOSFET caused by the parasitic resistance can be suppressed. It is thus possible to partly compensate for the loss of the driving force caused by an increase in the silicide resistance in the active area 1 associated with the use of more fine-shrunk structures.

The step-like variation of the planar pattern of the gate electrode shown in FIG. 1A is not limited to three levels as described previously. It may be varied to four levels as shown in FIG. 2 or to two levels (not shown). Alternatively, the pattern may be continuously varied so that the gate length of the gate electrode 2 decreases gradually as shown by the broken line in FIG. 2. The previously described advantages are also obtained in each of these modification cases. Furthermore, the planar pattern of the gate electrode 2 is not limited to the one in which the gate length is laterally symmetric as described previous embodiment and modifications. For example, the previously described advantages can be obtained even if the gate length is laterally asymmetric and varies step by step among a plurality of levels. In the case as shown in FIG. 3, for example, the gate electrode 2 has two steps in the side facing the source contact 3 and a straight-lined side facing the drain contact 4.

### Second Embodiment

In the first embodiment, the gate length decreases with increasing distance between the position of the gate electrode 2 and the position of the source contact 3. Alternatively, if it is desirable to reduce the effect of a drain resistance in connection with circuit operations, the positional relationship between the source contact 3 and the drain contact 4 in FIG. 1A may be reversed as shown in FIG. 1B.

That is, if only one gate electrode 2 is provided in one active area 1 and the source contact 3 and the drain contact 4 are diagonally arranged as shown in FIG. 1B, then the shape of the gate electrode 2 may be laterally symmetric and varies step by step among a plurality of levels, for example, as shown in the figure so that its gate length decreases with increasing distance between the position of the gate electrode 2 and the position of the drain contact 4.

With this arrangement, in a MOSFET having only one gate electrode in an active area as in the case with, for example, a CMOS inverter, if it is desirable to suppress an increase in a drain-side parasitic resistance, then the DIBL can be adjusted for MOSFET operations in a cross section perpendicular to the gate electrode so as to be equal at any positions with respect to the gate. That is, the DIBL can be adjusted at an arbitrary position along the gate electrode for MOSFET operations in the cross section perpendicular to the gate electrode. Accordingly, a decrease in the driving force of the MOSFET can be suppressed. It is thus possible to partly compensate for the loss of the driving force caused by an increase in the silicide resistance in the active area associated with the use of more fine-shrunk structures.

Also in the MOSFET having the latelally asymmetric gate electrode 2 shown in FIG. 3, the shape of the gate electrode may vary step by step among a plurality of levels or continuously. Thus, the gate electrode may be laterally symmetric or asymmetric as in the case with the previously described variation of the first embodiment. The previously described advantages are performed in each of these embodiments of modification cases.

### Third Embodiment

FIG. 4 is a diagram showing an example of a planar pattern of one of a PMOSFET and an NMOSFET forming a CMOS inverter according to a third embodiment.

In FIG. 4, reference numeral 1 denotes an active area surrounded by an STI area. Reference numeral 2 denotes a gate electrode on the active area 1. Reference numerals 3 and 4 denote a source contact and a drain contact.

In this MOSFET, if only one gate electrode 2 is provided in one active area 1 and the source contact 3 and the drain contact 4 are arranged at the same end of the gate electrode 1 in the longitudinal direction (the channel or gate width direction of the MOSFET), the shape of the gate electrode 2 is, for example, laterally symmetric and varies step by step among three levels in such a manner that the gate length increases with increasing distance between the position of the source contact 3 and the position of the drain contact 4.

With this arrangement, in the MOSFET having only one gate electrode 2 in an active area 1 as in the case with, for example, a CMOS inverter, if the source contact 3 and the drain contact 4 are arranged at the same end of the gate electrode 2 in the active area 1 in the channel or gate width direction, then the DIBL can be adjusted for MOSFET operations in a cross section perpendicular to the gate electrode 2 so as to be equal at any positions with respect to the gate electrode 2. That is, the DIBL can be adjusted at an arbitrary position along the gate electrode 2 for MOSFET operations in the cross section perpendicular to the gate electrode. Accordingly, a decrease in the driving force of the MOSFET can be suppressed. It is thus possible to partly compensate for the loss of the driving force caused by an increase in the silicide resistance in the active area associated with the use of more fine-shrunk structures.

If the source contact 3 and the drain contact 4 are arranged laterally symmetrically with respect to the gate electrode 2, for example, even if the source contact 3 and the drain contact 4 are arranged in a central portion of the active area 1 with respect to the longitudinal direction of the gate electrode 2, similar effects can be produced by implementing the semiconductor device in conformity with the above described second embodiment.

Also in the MOSFET shown in FIG. 4, the shape of the gate electrode may vary step by step among arbitrary plural levels or continuously or may be laterally symmetric or asymmetric as in the previously described variation of the first embodiment. The previously described advantages are obtainable in each of these cases.

### Fourth Embodiment

FIG. 5 shows an example of a planar pattern of a MOSFET circuit area in which a plurality of MOSFETs (four transistors, in this case) are arranged (vertically stacked) so as to be connected in series according to a fourth embodiment of the present invention. In this case, one source contact 3 and one drain contact 4 are diagonally arranged in the active area 1. Furthermore, no leading wire is provided in a source or drain area of each intermediate MOSFET.

In FIG. 5, reference numeral 1 denotes the active area surrounded by an STI area. Reference numerals 2a to 2d denote gate electrodes of four MOSFETS on the active area 1. Reference numerals 3 and 4 denote a source contact and a drain contact.

In the group of MOSFETS in the MOSFET circuit area or active area 1, one electrode 2a of the plurality of gate electrodes 2a to 2d which is closest to the source contact 3 is formed so that its gate length decreases with increasing distance from the source contact 3. Furthermore, the gate electrode 2d which is closest to the drain contact 4 is formed so that its gate length decreases with increasing distance from the drain contact 4.

With this arrangement, if a plurality of MOSFETS are connected in series as in the case with a NAND type memory unit in a NAND type flash memory, the DIBL can be adjusted at an arbitrary position along the longitudinal direction of the gate electrode 2a and/or 2d for MOSFET operations in a cross section perpendicular to the gate electrode 2a and/or 2d.

Specifically, for the gate electrode 2a closest to the source contact 3, MOSFET operations in a cross section perpendicular to the gate electrode 2a at a position far from the source contact 3 can be adjusted to undergo DIBL equivalent to that acting on MOSFET operations in a cross section perpendicular to the gate electrode 2a near the source contact 3. Likewise, MOSFET operations in a cross section perpendicular to the gate electrode 2d at a position far from the drain contact 4 can be adjusted to undergo DIBL equivalent to that acting on MOSFET operations in a cross section perpendicular to the gate electrode 2d near the drain contact 4.

Accordingly, a decrease in the driving force of the MOSFETS can be suppressed. It is thus possible to partly compensate for the loss of the driving force caused by an increase in the silicide resistance in the active area associated with the use of more fine-shrunk structures.

### Modifications of the Fourth Embodiment

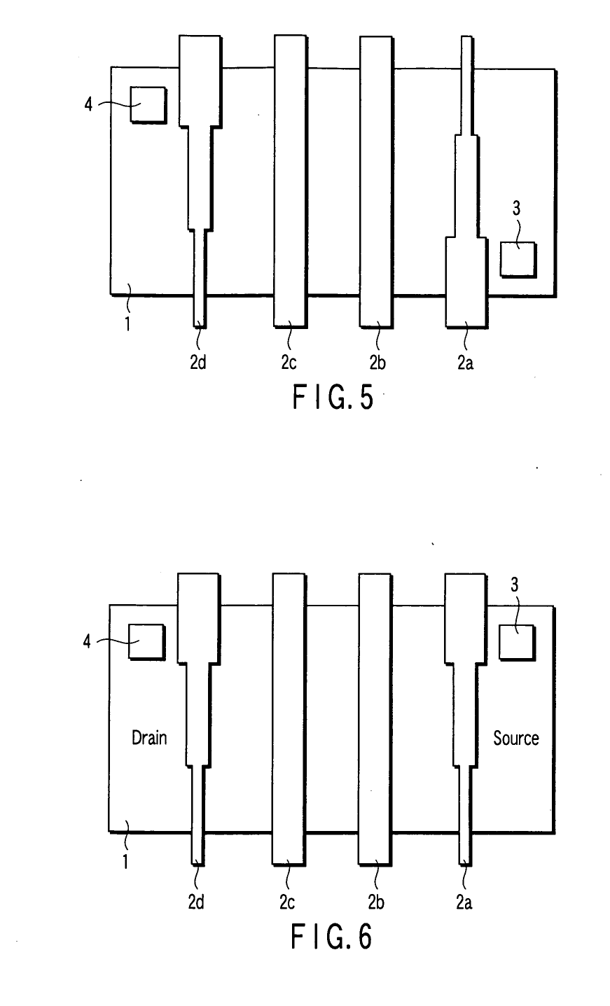

FIG. 6 shows an example of a planar pattern of a MOSFET circuit area in which a plurality of (four, in this case) MOSFETS are arranged so as to be connected in series according to a modification of the semiconductor device of the present invention. In this case, one source contact 3 and one drain contact 4 are arranged at the same end of the gate electrodes 2a and 2d in the channel or gate width direction. Furthermore, no lead wire is provided in a source or drain area of each of the intermediate MOSFETS formed with respect to the gate electrodes 2b and 2c.

In FIG. 6, reference numeral 1 denotes an active area surrounded by an STI area. Reference numerals 2a to 2d denote gate electrodes for forming four MOSFETS on the active area 1. Reference numerals 3 and 4 denote a source contact and a drain contact.

In the group of MOSFETS in the MOSFET circuit area 1, for the electrodes 2a and 2d of the plurality of gate electrodes 2a to 2d which are closest to the source contact 3 and the drain contact 4, respectively, MOSFET operations in cross sections perpendicular to the gate electrodes 2a and 2d at positions far from the source contact 3 and the drain contact 4 can be adjusted to undergo DIBL equivalent to those acting on MOSFET operations in cross sections perpendicular to the gate electrodes near the source contact 3 and the drain contact 4. Accordingly, a decrease in the driving force of the MOSFET can be suppressed.

Also in the MOSFET circuit area shown in FIG. 5 or FIG. 6, the shape of the gate electrodes 2a and/or 2d may vary step by step among arbitrary plural levels or continuously or may be laterally symmetric or asymmetric as in the previously described variation of the first embodiment. The previously described advantages are obtainable in each of these cases.

### Fifth Embodiment

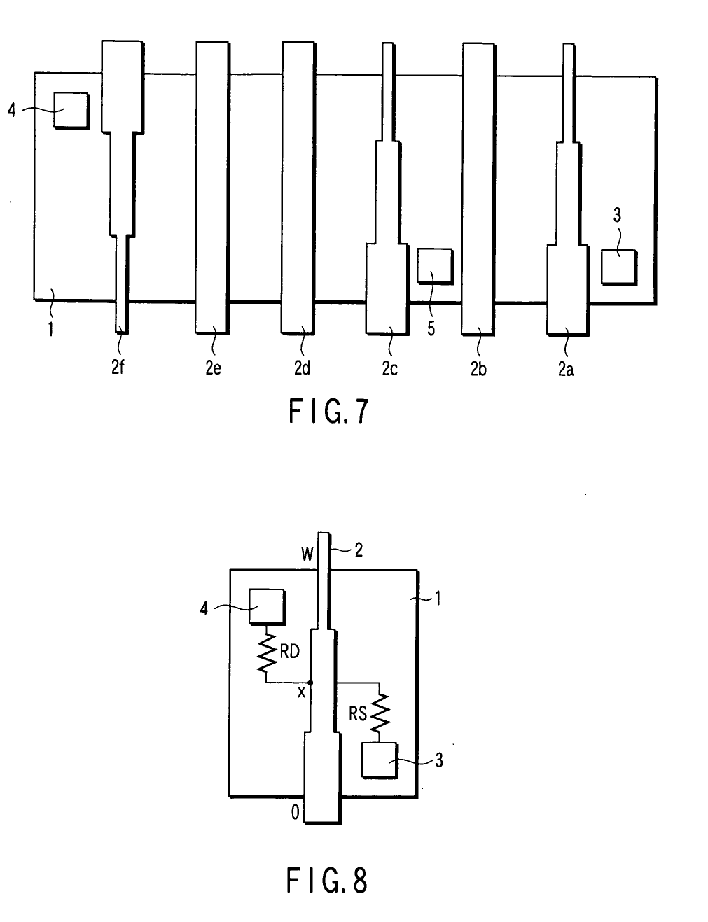

FIG. 7 shows an example of a planar pattern of a MOSFET circuit area in which a plurality of MOSFETS (six MOSFETS, in this case) are arranged so as to be connected in series according to a fifth embodiment of a semiconductor device of the present invention. In this case, a lead contact 5 is provided in a source/drain area of one of the intermediate MOSFETs.

In FIG. 7, reference numeral 1 denotes an active area surrounded by an STI area. Reference numerals 2a to 2f denote gate electrodes on the active area 1. Reference numerals 3 and 4 denote a source contact and a drain contact.

In the group of MOSFETs in the MOSFET circuit area of FIG. 7, one electrode 2a of the plurality of gate electrodes 2a to 2f, which is closest to the source contact 3 is formed so that its gate length decreases with increasing distance from the source contact 3. Furthermore, the gate electrode 2f which is closest to the drain contact 4 is formed so that its gate length decreases with increasing distance from the drain contact 4. Moreover, the gate electrode 2c closest to the lead contact 5 is formed so that its gate length decreases with increasing distance from the lead contact 5.

With this arrangement, if a plurality of MOSFETs are connected in series as in the case with a NAND type memory unit in a NAND type flash memory and the lead contact 5 is provided in the source/drain area of one of the intermediate MOSFET, then for the gate electrode 2a, 2f or 2c closest to the source contact 3, the drain contact 4, or the lead contact 5, MOSFET operations in a cross section perpendicular to the gate electrode 2a, 2f or 2c at a position far from the source contact 3, the drain contact 4, or the lead contact 5 can be adjusted to undergo DIBL equivalent to that acting on MOSFET operations in a cross section perpendicular to the gate electrode 2a, 2f or 2c near the source contact 3, the drain contact 4, or the lead contact 5. Accordingly, a decrease in the driving force of the MOSFET or MOSFETS can be suppressed.

Also in this MOSFET circuit area, the shape of the gate electrode may vary step by step among arbitrary plural levels or continuously or may be laterally symmetric or asymmetric as in the previously described modification of the first embodiment. The previously described advantages are obtainable in each of these cases.

Now, description will be given of a method of determining the gate length in accordance with the distance from the position of the source/drain contact to the position of the gate electrode. Here, the first embodiment will be taken by way of example, and for simplification of calculations, the case will be shown in which the driving force of a triode area of a MOSFET is to be improved.

FIG. 8 is a plan view illustrating a path of a current flowing through a position x of the gate electrode 2 in the MOSFET shown in FIG. 1A as well as its parasitic resistance.

As shown in FIG. 8, in the active area 1, the start and end points of the gate electrode 2 of the MOSFET in the channel width direction are defined as 0 and W, respectively, a parasitic resistance from the position x on the gate electrode 2 to the source contact 3 is defined as RS, a parasitic resistance from the position x on the gate electrode 2 to the drain contact 4 is defined as RD, and a current per unit length flowing through the position x on the gate electrode 2 is defined as I(x). An on current Ion and an off current Ioff through the MOSFET are expressed by the following equations:

$$\begin{matrix}{I}_{on} = {\int }_{0}^{W} ⅆ x I ( x ) & ( 1 ) \\ {I}_{on} ( x ) = {μ}_{eff} {C}_{ox} \frac{W}{{L}_{gate} ( x )} ( {V}_{g} - {V}_{t} ( x ) ) {V}_{SD} ( x ) & ( 2 ) \\ {I}_{off} ( x ) = {μ}_{eff} \frac{W}{{L}_{gate} ( x )} \sqrt{\frac{{ϵ}_{Si} q {N}_{a}}{4 {ψ}_{B}}} {( \frac{kT}{q} )}^{2} {ⅇ}^{- \frac{2.3 {V}_{t} ( x )}{S}} ( 1 - {ⅇ}^{- \frac{q {V}_{SD} ( x )}{kT}} ) & ( 3 )\end{matrix}$$

where Lgate(x) denotes the gate length at the position x on the gate electrode 2.

In this case, to allow the current Ioff to have the same current density all over the area along the gate electrode 2, Lgate(x) must meet the following equation:

$${L}_{gate} ( x ) = \frac{{ⅇ}^{- \frac{2.3 {V}_{{t}_{( x )}}}{S}} ( 1 - {ⅇ}^{- \frac{{qV}_{SD} ( x )}{kT}} )}{{ⅇ}^{- \frac{2.3 {V}_{t}^{0}}{S}} ( 1 - {ⅇ}^{- \frac{{qV}_{SD}^{0}}{kT}} )} {L}_{gate}^{0} \qquad ( 4 )$$

where Vt⁰ and VSD⁰ denote certain constants. Furthermore, VSD(x) denotes the source-drain voltage at the position x on the gate electrode 2.

$${V}_{SD} ( x ) = \frac{{V}_{DD}}{1 + \frac{{μ}_{eff} {C}_{ox} W ( {V}_{g} - {V}_{t} ( x ) ) ( {R}_{D} ( x ) + {R}_{S} ( x ) )}{{L}_{gate} ( x )}} \qquad ( 5 )$$

In the above equation, RD(x) denotes the drain-side parasitic resistance at the position x on the gate electrode 2. RS(x) denotes the source-side parasitic resistance at the position x on the gate electrode 2.

By applying Lgate(x) that simultaneously meets Equations (4) and (5) for the given values of Vt, RD(x), and RS(x), it is possible to ensure only the gate length required to maintain the current density of the current Ioff at a certain value or less at all positions x along the gate electrode 2. As a result, the driving force of the MOSFET can be improved.

As an actual example of a calculation, the case will be shown in which μeff=200 cm²/Vs, W=0.7 μm, S=80 mV/dec., Vdd=1.2V, Cox=2.03e−2F/m², RD=RS=20Ω, and Vt(x)=0.3+5e 4x (x: distance from the source contact 3 along the gate electrode 2).

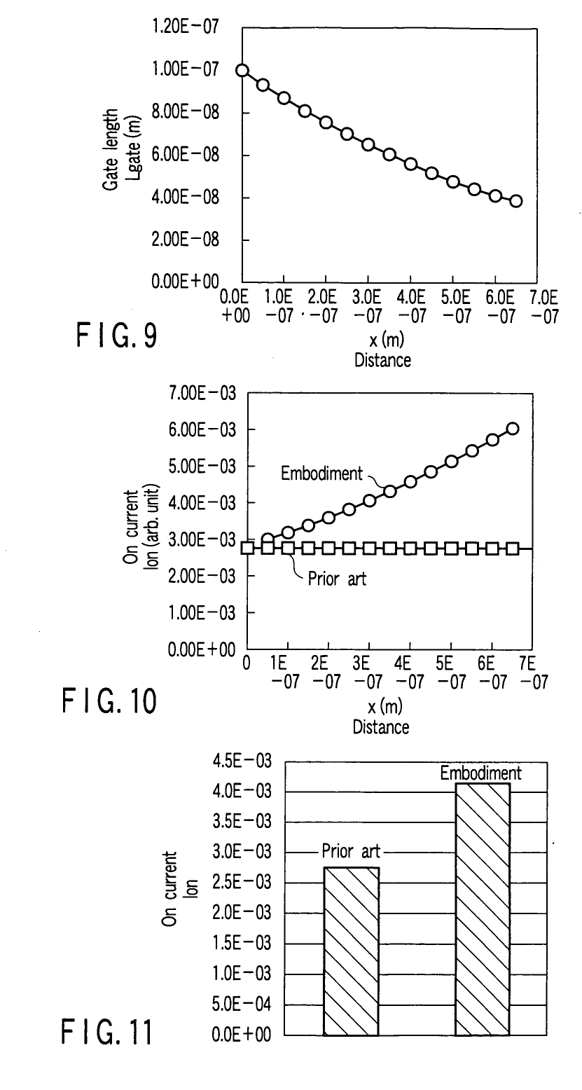

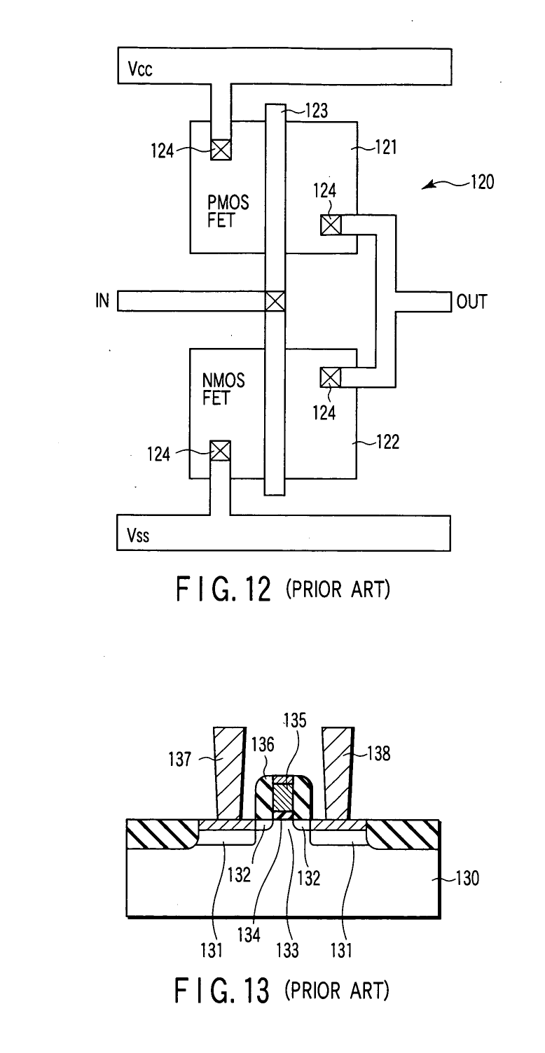

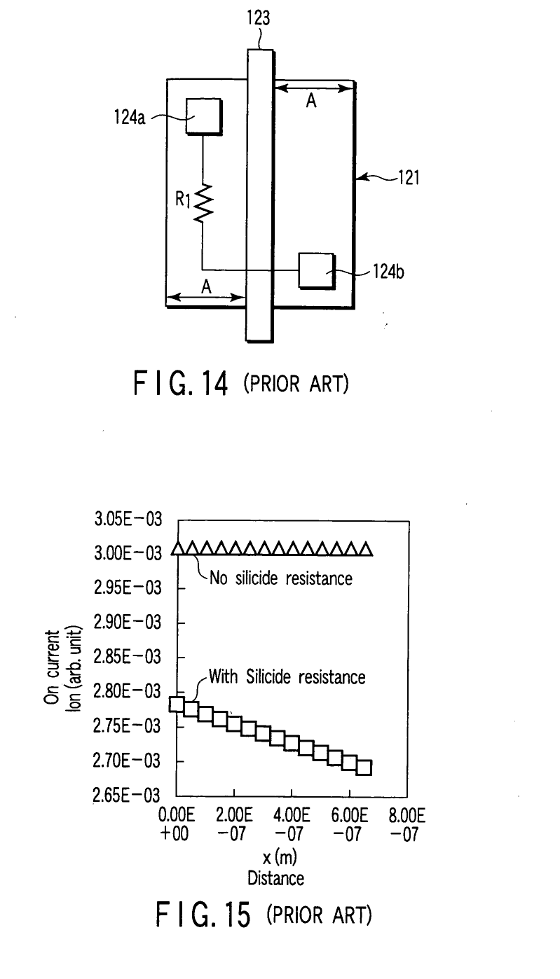

FIG. 9 shows the relationship between the distance x from the source contact 3 along the gate electrode 2 and the gate length Lgate in the MOSFET in FIG. 1, in which the gate length Lgate is determined in accordance with the distance x so as to simultaneously establish Equations (4) and (5).

FIG. 9 shows that the gate length Lgate should be decreased with increasing distance between the gate electrode 2 and the source contact 3 in order to improve the driving force of the MOSFET shown in FIG. 1.

FIG. 10 is a characteristic diagram showing the relationship between the distance x and the current Ion (driving current density distribution) in a MOSFET for which the relationship between the distance x and the gate length Lgate has been determined as shown in FIG. 9. For the sake of comparison, this figure also shows the relationship between the distance x and the current Ion in a prior art MOSFET.

FIG. 10 indicates that the MOSFET according to the present embodiment can increase the current density in an area along the gate electrode far from the source contact 3.

FIG. 11 is a characteristic diagram showing the magnitude of the on current Ion obtained if a standby current remains fixed, by comparing a prior art MOSFET with the MOSFET for which the relationship between the distance x and the gate length Lgate has been determined as shown in FIG. 9.

FIG. 11 indicates that the MOSFETS according to the embodiments of the present invention can increase the on current Ion (can increase a ratio Ion/Ioff) while keeping the standby current fixed compared to the prior art MOSFET.

In the above calculation, it is assumed that the relationships shown in Equations (2) to (5) are established in order to simplify the analysis. However, Equations (2) to (5) can be defined in accordance with the actual situation. Furthermore, the distribution of the gate length Lgate shown in FIG. 10 can be approximated in the form of two or more steps with respect to the gate length.

In the above embodiments, the silicide layer is formed on the surface of the drain and source diffusion layers in the active area of the MOSFET. However, even if the silicide layer is not formed, the previously described advantages can be obtained.

As described above, according to the present invention, it is possible to prevent a decrease in the driving force of the MOSFET caused by the parasitic resistance of the drain and source diffusion layers in the active area of the MOSFET.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
an active area of a MOSFET separated by an element isolation area on a semiconductor substrate;
at least one gate electrode provided to pass over the active area; and
at least one source/drain contact formed on a surface of the active area at one side of the gate electrode,
wherein the gate electrode has a shape to vary so that a gate length decreases with increasing a distance from a position of the source/drain contact along the gate electrode.

2. The semiconductor device according to claim 1, wherein one gate electrode is provided in the active area, and source/drain contacts are arranged at respective sides of the gate electrode at diagonal positions in the active area.

3. The semiconductor device according to claim 2, wherein the MOSFET is one of a PMOSFET and an NMOSFET of a CMOS inverter.

4. The semiconductor device according to claim 1, wherein one gate electrode is provided in the active area, and source/drain contacts are arranged at one end of the gate electrode in a channel width direction.

5. The semiconductor device according to claim 1, wherein the gate electrode has a planar pattern such that the gate length varies in a laterally symmetrical form.

6. The semiconductor device according to claim 1, wherein the gate electrode has a planar pattern such that the gate length varies in a laterally asymmetrical form.

7. The semiconductor device according to claim 1, wherein a silicide layer is formed on the surface of the active area at the opposite sides of the gate electrode, and the source/drain contact is in contact with the silicide layer.

8. A semiconductor device comprising:
an active area separated by an isolation area on a semiconductor substrate and in which a plurality of MOSFETS are arranged so as to be connected in series in the active area;
a plurality of gate electrodes juxtaposed with each other so as to pass over the active area;
a first source/drain contact formed at a side of the juxtaposed gate electrodes and in contact with a surface of the active area, and
a second source/drain contact formed at another side of the juxtaposed gate electrodes and in contact with a surface of the active area,
wherein the shape of the gate electrode located closest to one of the first and second source/drain contacts is formed to vary step by step or continuously so that a gate length decreases with increasing a distance from a position of one of the first and second source/drain contacts along the gate electrode.

9. A semiconductor device according to claim 8, further comprising at least one intermediate source/drain contact formed in contact with a source/drain area of an intermediate MOSFET corresponding to an intermediate one of the plurality of gate electrodes, and
wherein the gate electrode located closest to the intermediate source/drain contact has a shape formed to vary step by step or continuously so that the gate length decreases with increasing distance from the position of the intermediate source/drain contact along the gate electrode.

10. The semiconductor device according to claim 8, wherein the plurality of MOSFETS form a NAND type memory unit in a NAND type flash memory.

11. The semiconductor device according to claim 8, wherein the first and second source/drain contacts arranged at the respective sides of the gate electrode are arranged at diagonal positions in the active area.

12. The semiconductor device according to claim 8, wherein the first and second source/drain contacts arranged at the respective sides of the gate electrode are arranged at the same end of the gate electrode in a channel width direction.

13. The semiconductor device according to claim 8, wherein the gate electrode has a planar pattern such that the gate length varies in a laterally symmetrical form.

14. The semiconductor device according to claim 8, wherein the gate electrode has a planar pattern such that the gate length varies in a laterally asymmetrical form.
